(19) United States
(12) Patent Application Publication
(10) Pub. No.: US 2025/0319562 A1
(43) Pub. Date: Oct. 16, 2025

(54) BONDING APPARATUS, DETERMINATION APPARATUS, AND METHOD OF MANUFACTURING ARTICLE

(71) Applicant: CANON KABUSHIKI KAISHA, Tokyo (JP)

(72) Inventor: MASAHIRO KIMURA, Tochigi (JP)

(21) Appl. No.: 19/094,085

(22) Filed: Mar. 28, 2025

(30) Foreign Application Priority Data
Apr. 12, 2024 (JP) 2024-064427

(51) Int. Cl. B23Q 3/155; H01L 23/00

(52) U.S. Cl. CPC B23Q 3/1556; H01L 24/74; H01L 24/80; H01L 2224/74; H01L 2224/80

(57) ABSTRACT

An apparatus for bonding a die and a bonded object is provided that includes a holding unit configured to hold the die, and a determination unit configured to determine replacement of the holding unit based on history information about bonding the die to the bonded object using the holding unit. The history information is an accumulated value of a use record when a plurality of dies is bonded to at least one of a plurality of bonded objects.

### BACKGROUND

### Field

The present disclosure relates to a bonding apparatus, a determination apparatus, and a method of manufacturing an article.

### Related Art

As a semiconductor manufacturing apparatus that manufactures a semiconductor device or the like, there is a bonding apparatus that bonds a plurality of dies to a bonded object (e.g., substrate). The bonding apparatus performs processing of bonding each die held by a head to the bonded object. A jig (collet) that comes into contact with the die is disposed at a tip the head.

Japanese Patent Application Laid-Open No. 2019-75446 discusses a method of replacing the collet based on a detection result of the shape of the collet by a collet inspection unit including a shape detection sensor.

However, in a method of determining whether to replace the collet based on the detection result of the shape of the collet, it takes time to detect the shape of the collet.

### SUMMARY

The present disclosure is directed to a bonding apparatus capable of determining whether to replace a collet while preventing a decrease in productivity.

According to an aspect of the present disclosure, an apparatus for bonding a die and a bonded object includes a holding unit configured to hold the die, and a determination unit configured to determine replacement of the holding unit based on history information about bonding the die to the bonded object using the holding unit, wherein the history information is an accumulated value of a use record when a plurality of dies is bonded to at least one of a plurality of bonded objects.

Further features of the present disclosure will become apparent from the following description of exemplary embodiments with reference to the attached drawings.

### BRIEF DESCRIPTION OF THE DRAWINGS

FIG. 1 is a diagram illustrating a configuration of a bonding apparatus according to a first exemplary embodiment.

FIGS. 2A and 2B are diagrams illustrating a head holding a die.

FIG. 3 is a diagram illustrating a substrate stage as viewed from a +Z-axis direction.

FIG. 4 is a flowchart of a bonding method according to the first exemplary embodiment.

FIG. 5 is a schematic diagram illustrating an inspection apparatus and a determination apparatus according to a second exemplary embodiment.

FIG. 6 is a flowchart of a process for determining replacement of a collet according to the second exemplary embodiment.

FIG. 7 is a flowchart of a method of manufacturing an article according to a third exemplary embodiment.

### DESCRIPTION OF THE EMBODIMENTS

Hereinafter, exemplary embodiments of the present disclosure will be described with reference to the drawings. The following exemplary embodiments do not limit the disclosure. While a plurality of features is described in the exemplary embodiments, not all of the plurality of features is necessarily essential to the disclosure, and the exemplary embodiments may be freely combined. Furthermore, in the drawings, the same or similar components are denoted by the same reference numerals, and redundant descriptions will be omitted.

In the specification and the drawings, directions are indicated by an XYZ coordinate system in which a vertical direction is a Z axis, a horizontal plane perpendicular to the vertical direction is an XY plane, and axes are orthogonal to each other.

Specific configurations according to respective exemplary embodiments are described below.

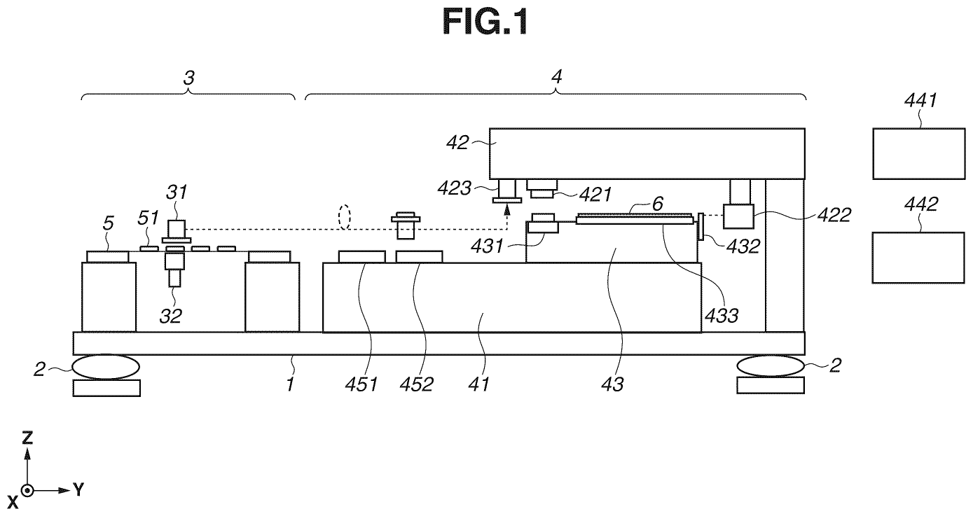

FIG. 1 is a diagram illustrating a configuration of a bonding apparatus according to a first exemplary embodiment. The bonding apparatus is configured to bond a die 51 and a bonded object 6. The die 51 may be a die singulated through a dicing process (cutting process), a die in which some singulated dies are stacked, a small piece of a material, an optical element, or a structure such as a microelectromechanical system (MEMS).

The bonded object 6 may be a silicon wafer, a silicon wafer with wiring formed thereon, a glass wafer, a glass panel with wiring formed thereon, a printed-wiring board (PWB) with wiring formed thereon, a printed circuit board (PCB) mounted with an electronic part, or a metal panel. Alternatively, the bonded object 6 may be a substrate in which a die with a semiconductor device formed thereon is bonded to a wafer with a semiconductor device formed thereon.

The present exemplary embodiment does not limit the bonding method of the die 51 and the bonded object 6 to a specific bonding method. The method of bonding may include bonding with an adhesive, temporary bonding with a temporary bond, hybrid bonding, atomic diffusion bonding, vacuum bonding, and bump bonding, and various temporary bonding methods and permanent bonding methods can be used.

The bonding apparatus may include a pickup unit 3 and a bonding unit 4 mounted on a base 1 vibration-damped by a mount 2. The bonding apparatus bonds dies 51 that are aligned on a dicing tape attached to a dicing frame 5 to certain positions on the bonded object 6. In the example illustrated in FIG. 1, the pickup unit 3 and the bonding unit 4 are mounted on the same base 1. However, the pickup unit 3 and the bonding unit 4 may be mounted on different bases.

The pickup unit 3 may include a pickup head 31 and a release head 32. The release head 32 peels off the dicing tape from each die 51, and the pickup head 31 suctions onto the die 51 that has been peeled off from the dicing tape by the release head 32. The pickup head 31 rotates around a Y-axis so as to position the suctioned die 51 on a +Z direction side relative to the pickup head 31, and transfers the die 51 to a bonding head 423.

In the present exemplary embodiment, the pickup head 31 rotates to transfer the die 51 to the bonding head 423. However, the example is not restrictive. For example, two or more die holding units may be provided, and the die 51 may be relayed and transferred between the die holding units and then transferred to the bonding head 423. Alternatively, the bonding head 423 may be configured to move to receive the die 51 by a driving mechanism of the bonding head 423.

To improve productivity, a plurality of pickup units, a plurality of pickup heads, a plurality of release heads, and a plurality of bonding heads may be arranged.

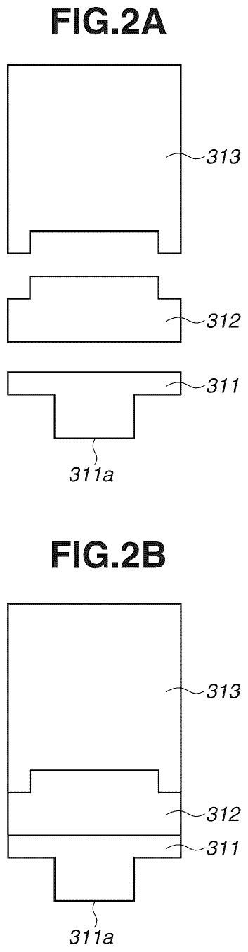

FIGS. 2A and 2B are diagrams illustrating a head holding the die 51. The head is the pickup head 31 or the bonding head 423. The head that holds the die 51 includes a collet holder 312 holding a collet 311, and a main body unit 313 holding the collet holder 312. The collet holder 312 holds the collet (first holding unit) 311 (jig) coming into contact with the die 51. FIG. 2A illustrates a state where the collet 311, the collet holder 312, and the main body unit 313 are separated. FIG. 2B illustrates a state where the collet 311, the collet holder 312, and the main body unit 313 are integrated. When bonding processing is performed, the collet 311, the collet holder 312, and the main body unit 313 are integrated, as illustrated in FIG. 2B.

Holding of the collet holder 312 by the main body unit 313 and holding of the collet 311 by the collet holder 312 are performed by, for example, suctioning gas in a space between a holding object and an object to be hold. Alternatively, holding of the collet holder 312 by the main body unit 313 and holding of the collet 311 by the collet holder 312 are performed by a mechanism such as a claw or by magnetic force of a magnet.

The collet 311 holds the die 51 on a holding surface 311a. A material of the collet 311 is a fluoro rubber, a polyether ether ketone (PEEK) material, steel use stainless (SUS), or the like. Holding of the die 51 by the collet 311 is performed by, for example, suctioning gas in a space between the holding surface 311a and the die 51.

The collet holder 312 is held by the main body unit 313. On the other hand, the collet 311 may be replaced depending on a type of the die 51. Alternatively, the collet 311 may be replaced based on damage (wear) or contamination that occurs in sequentially bonding the plurality of dies 51.

For example, in a case where the collet 311 is replaced based on occurrence of damage or contamination, a used collet is disposed of in a collet discarding portion 451 illustrated in FIG. 1, and a new collet is supplied from a collet supplying portion 452 and is attached to the collet holder 312. Detachment and attachment of the collet 311 at this time may be performed by, for example, a collet replacement hand.

The bonding unit 4 includes a stage platen 41 and an upper base 42, and a substrate stage 43 is mounted on the stage platen 41. The substrate stage 43 can be driven in an XY direction and can be rotationally driven around a Z-axis by a driving unit such as a linear motor. The rotational operation need not be performed by the substrate stage 43, and the rotational operation may be performed by the bonding head 423.

A first observation camera 431 is mounted on the substrate stage 43. The first observation camera 431 measures a position of a feature point of the die 51, an outer dimension of the die 51, and distances of a plurality of points on a measurement surface in a height direction. Thus, the position, the outer dimension, and a flatness of the die 51 held by the bonding head 423 can be measured using the first observation camera 431.

A bar mirror 432 is disposed on a side surface of the substrate stage 43. The bar mirror 432 is a target of an interferometer 422. In addition, a substrate chuck (second holding unit) 433 that chucks (holds) the bonded object 6 is mounted on the substrate stage 43. A chucking method of a substrate by the substrate chuck 433 may be a vacuum suction method or an electrostatic adsorption method.

The upper base 42 supports a second observation camera 421, the interferometer 422 for measuring a position of the substrate stage 43, and the bonding head 423. The second observation camera 421 is a camera that measures a position of a feature point (element pattern, mark, etc.) of the bonded object 6 and distances of a plurality of points in the Z direction to measure a flatness, and is, for example, a camera that uses infrared light as a measurement light source.

The substrate stage 43 may include a driving mechanism. The substrate chuck 433 or the substrate stage 43 is driven in the +Z direction by the driving mechanism, and the die 51 and the bonded object 6 are brought close to and into contact with each other, and are then bonded. After the die 51 and the bonded object 6 are bonded, the substrate chuck 433 or the substrate stage 43 is driven in the −Z direction and is returned to an original position in the Z-axis direction. The driving mechanism may be included in the bonding head 423, and bonding operation of the die 51 and the bonded object 6 may be performed by driving the bonding head 423 in the Z-axis direction. Alternatively, the driving mechanism may be included in each of the substrate stage 43 and the bonding head 423, and the bonding operation of the die 51 and the bonded object 6 may be performed by driving the substrate chuck 433 or the substrate stage 43 and driving the bonding head 423 in the Z-axis direction. In other words, it is sufficient to provide a relative driving mechanism that relatively drives the bonding head 423 and the substrate chuck 433 by the driving mechanism so as to vary an interval between the die 51 and the bonded object 6.

When the die 51 and the bonded object 6 are bonded, the die 51 and the bonded object 6 may be brought into contact with and bonded to each other while the die 51 is deformed by controlling pressure in an internal space of the collet 311 holding the die 51.

A control unit 441 controls the units of the bonding apparatus. The control unit 441 also functions as a determination unit (determination apparatus) that determines whether to replace the collet 311 by a method described below.

The control unit 441 may include a computer (information processing apparatus) that includes a controller or processor, such as a central processing unit (CPU), and a storage unit, such as a memory. The control unit 441 may be disposed in a housing of the bonding apparatus, or may be disposed outside the housing. The control unit 441 disposed outside the housing of the bonding apparatus may be realized by, for example, a computer that functions as a control server connected to the bonding apparatus via a network. A storage unit 442 stores information including history information about bonding of the die 51 and the bonded object 6, i.e. bonding die 51 with/to bonded object 6, as described below.

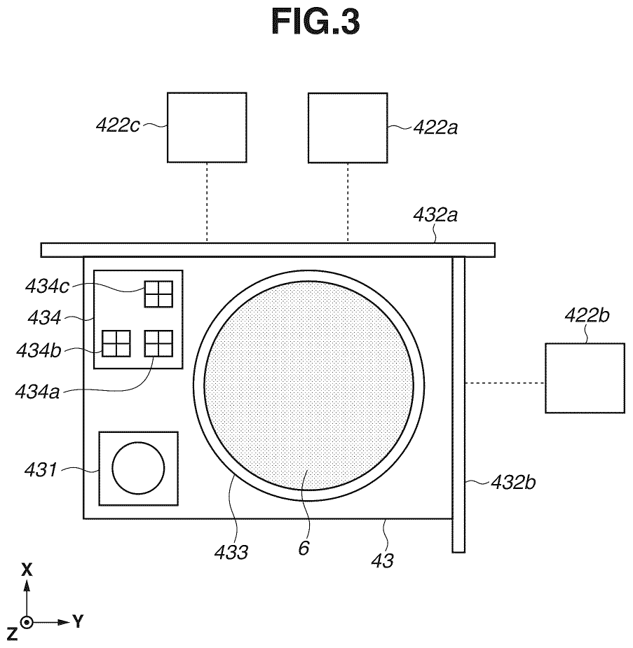

FIG. 3 is a diagram illustrating the substrate stage 43 as viewed from the +Z-axis direction. The bonded object 6 is held by the substrate chuck 433. The bar mirror 432 may include at least two bar mirrors so as to measure the position of the bonded object 6 in the X direction, the Y direction, and a rotation direction around the Z-axis. A bar mirror 432a is a target of an interferometer 422a that performs positional measurement in the X-axis direction, and is a target of an interferometer 422c that measures a rotation amount around the Z-axis based on a difference with the interferometer 422a. A bar mirror 432b is a target of an interferometer 422b that performs positional measurement in the Y-axis direction. The interferometer 422 measures the position in the X-axis direction, the position in the Y-axis direction, and the rotation amount around the Z-axis, of the substrate stage 43 in real time. The control unit 441 feedback-controls a stage driving unit in real time based on measurement results by the interferometer 422, thereby positioning the substrate stage 43 with high accuracy. As described above, the positioning according to the present exemplary embodiment is performed by the positional measurement with high accuracy by the interferometer and the feedback control based on a result of the positional measurement.

A reference plate 434 in which a plurality of marks (including marks 434a, 434b, and 434c) is drawn is disposed beside the substrate chuck 433. The reference plate 434 may have a low thermal expansion coefficient, and may have the marks drawn with high positional accuracy. For example, the reference plate 434 may be a reference plate in which the marks are drawn on a quartz substrate by using a drawing method in a semiconductor lithography process. The reference plate 434 may be provided at the same height as a surface of the bonded object 6 and may be observable by the second observation camera 421, without being limited to a case where a reference plate observation camera is separately provided. The substrate stage 43 may include a rough movement stage that can be driven in a large range, and a fine movement stage that is disposed on the rough movement stage and can be driven in a small range with high accuracy. In this case, to perform positioning with high accuracy, the first observation camera 431, the bar mirror 432, the substrate chuck 433, and the reference plate 434 may be fixed on the fine movement stage.

The control unit 441 guarantees an origin position, a magnification, directions (rotation) in the X-axis and the Y-axis, and an orthogonality of the substrate stage 43 by using an observation result of the reference plate 434 by the second observation camera 421. The mark 434a is observed by the second observation camera 421, and a measurement value of the interferometer when the mark 434a is positioned at a center of an image acquired by the camera is defined as an origin of the substrate stage 43. The mark 434b is observed by the second observation camera 421, and the direction of the Y-axis and a Y-magnification of the substrate stage 43 are determined from the measurement value of the interferometer when the mark 434b is positioned at the center of the image acquired by the camera.

The mark 434c is observed by the second observation camera 421, and the direction of the X-axis and an X-magnification of the substrate stage 43 are determined from the measurement value of the interferometer when the mark 434c is positioned at the center of the image acquired by the camera. In other words, calibration of the direction of the axis and the orthogonality is performed while a direction from the mark 434b toward the mark 434a of the reference plate 434 is defined as the Y-axis direction, and a direction from the mark 434c toward the mark 434a is defined as the X-axis direction. In addition, calibration is performed while an interval between the mark 434b and the mark 434a is defined as a scale reference in the Y-axis direction, and an interval between the mark 434c and the mark 434a is defined as a scale reference in the X-axis direction. The measurement value of the interferometer is varied due to change in refractive index of an interferometer optical path caused by pressure variation and temperature variation. Thus, calibration may be performed at a timing to guarantee the origin position, the magnification, the rotation, and the orthogonality of the substrate stage 43. To reduce variation of the measurement value of the interferometer, a temperature of a space where the substrate stage 43 is disposed may be controlled by a temperature controlled chamber.

In the above-described example, the reference plate 434 on the substrate stage 43 is observed by the second observation camera 421. In place of such a form, the reference plate 434 may be attached to the upper base 42, and may be observed by the first observation camera 431. With the configuration, the origin position, the magnification, the rotation, and the orthogonality of the substrate stage 43 can be guaranteed.

In the above-described example, the calibration is performed by observing the reference plate 434. Alternatively, for example, calibration may be performed by contacting operation to a reference surface, or positioning with high accuracy may be performed using a position measurement unit in which an absolute value is guaranteed, such as a white light interferometer.

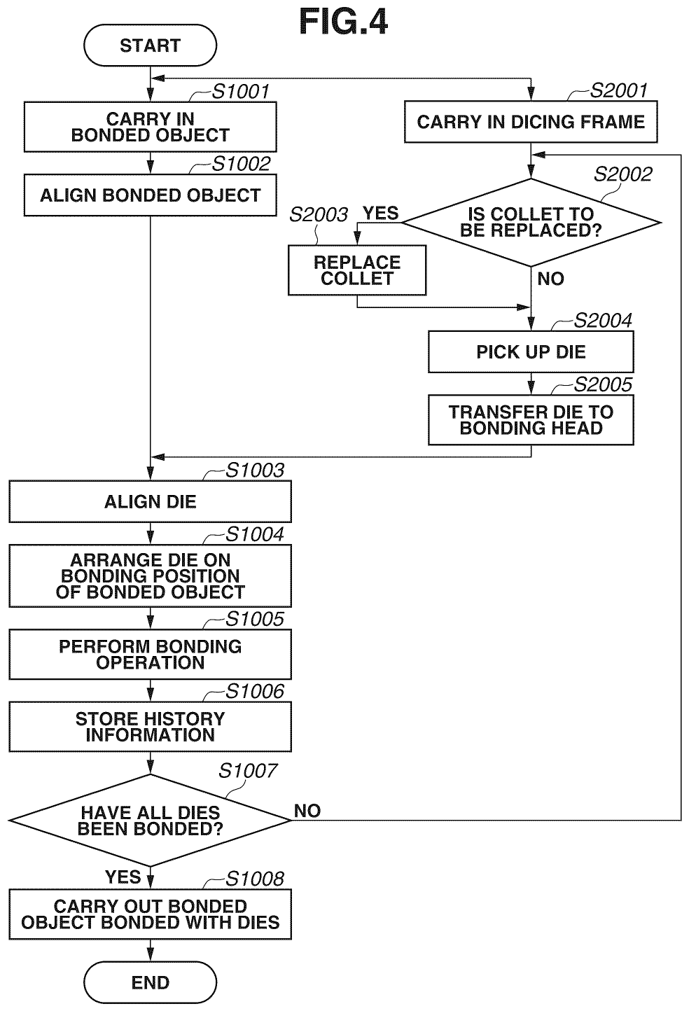

FIG. 4 is a flowchart of a bonding method according to the present exemplary embodiment. In step S1001, the bonded object 6 is carried in by a conveyance apparatus. If foreign matter or contaminant adheres to a bonding surface of the die 51 or the bonded object 6, a bonding failure occurs. Thus, the inside of the bonding apparatus may be a Class 1 cleanroom or the like. To maintain high cleanliness of the bonded object 6, the bonded object 6 is housed in a container that has high airtightness and high cleanliness, such as a Front Opening Unified Pod (FOUP), and is carried in the bonding apparatus from the container. In addition, to increase cleanliness, the bonded object 6 may be cleaned in the bonding apparatus after the substrate is carried in. Further, pretreatment for bonding is also performed. For example, in a case where bonding is performed using an adhesive, the adhesive is applied to the bonded object 6. In a case where bonding is performed by hybrid bonding, treatment for activating the surface of the bonded object 6 is performed. By a pre-alignment unit, adjustment of the bonded object 6 in the rotation direction based on a notch or an orientation flat provided on the bonded object 6 and rough positioning of the bonded object 6 based on an outer shape of the bonded object 6 are performed. Then, the bonded object 6 is held by the substrate chuck 433 on the substrate stage 43.

In step S1002, the control unit 441 performs control to align the bonded object 6 based on the measurement result of the position of the bonded object 6 by the second observation camera 421. Focus adjustment of the second observation camera 421 may be performed by a focus adjustment mechanism provided in the second observation camera 421, or may be performed by moving the bonded object 6 in the Z-axis direction by the driving mechanism of the substrate stage 43. Alignment measurement may be performed by measuring an alignment mark previously formed on the bonded object 6. In a case where no alignment mark is formed on the bonded object 6, the alignment measurement is performed by measuring a feature point, a position of which can be specified. The control unit 441 measures the position of the feature point by measuring a projected image position of the feature point relative to the center of the image acquired through imaging by the second observation camera 421. To perform measurement with high accuracy relative to a reference point of the bonding apparatus, the substrate stage 43 is previously driven such that the marks formed on the reference plate 434 are within a visual field of the second observation camera 421, and the positions of the marks on the reference plate 434 are measured by the second observation camera 421. An offset amount to a measurement position measured by the second observation camera 421 is determined from the driving position of the substrate stage 43 at this time and the positions of the marks measured by the second observation camera 421. This makes it possible to measure the position with high accuracy relative to the reference point of the bonding apparatus. In addition, during the processing in step S1002, a surface position of the bonding surface of the bonded object 6 may be measured using a height measurement unit. A thickness of the bonded object 6 is varied depending on a position. To manage a gap between the die 51 and the bonded object 6 with high accuracy in the bonding operation, the surface position of the bonded object 6 is important. In a case where the bonded object 6 is a substrate or a panel on which a pattern is not formed, alignment in step S1002 may not be performed.

The processing relating to the bonded object 6 is described above. Next, processing relating to the die 51 that is performed in parallel with step S1001 and step S1002 is described.

In step S2001, the dicing frame 5 is carried in by a conveyance apparatus. The dicing tape is attached to the dicing frame 5, and the dies 51 are arranged on the dicing tape.

In step S2002, the control unit (determination unit) 441 determines whether to replace the collet 311 based on the information stored in the storage unit 442 (determination step). The determination in step S2002 may be performed on a collet included in the pickup head 31 or on a collet included in the bonding head 423. Alternatively, the determination in step S2002 may be performed on both the collet included in the pickup head 31 and the collet included in the bonding head 423. Details of the determination in step S2002 are described below.

In a case where it is determined in step S2002 that the collet 311 is to be replaced (YES in step S2002), the collet 311 is replaced in step S2003, and the processing proceeds to step S2004. The collet 311 is replaced by the collet replacement hand, as described above. In a case where it is determined in step S2002 that the collet 311 is not to be replaced (NO in step S2002), the processing proceeds to step S2004 without performing the processing in step S2003.

In step S2004, the pickup head 31 picks up one die 51. In step S2004, the control unit 441 moves the pickup head 31 and the release head 32 to the position of the die 51 that is to be picked up. Next, the release head 32 peels the die 51 from the dicing tape while the pickup head 31 suctions onto the die 51, and the pickup head 31 holds the die 51.

In step S2005, the control unit 441 controls the pickup head 31 to transfer the die 51 to the bonding head 423. During the processing in step S2005, pretreatment for bonding may be performed. The pretreatment may be, for example, treatment of cleaning the die 51 and application of an adhesive to the die 51 in the case where bonding is performed using an adhesive. In the case where bonding is performed by hybrid bonding, the pretreatment may be treatment of activating the surface of the die 51.

In step S1003, the control unit 441 performs control to align the die 51 based on a measurement result of the position of the die 51 held by the bonding head 423 by the first observation camera 431. In step S1003, the control unit 441 drives the substrate stage 43 such that the feature point of the die 51 is within a visual field of the first observation camera 431. The feature point may be an element pattern or an alignment mark of the die 51. Alternatively, a whole or a part of an outer dimensional shape of the measured die 51 may be handled as the feature point. Focus adjustment of the first observation camera 431 may be performed by, for example, a focus adjustment mechanism of the first observation camera 431. Alternatively, the focus adjustment may be performed by driving the die 51 in the Z-axis direction by the driving mechanism of the bonding head 423. Alternatively, the focus adjustment may be performed by driving the first observation camera 431 in the Z-axis direction by the driving mechanism of the substrate stage 43 on which the first observation camera 431 is mounted.

During the processing in step S1003, a surface position of the die 51 may be measured using a height measurement unit. Thicknesses of the plurality of dies 51 is varied among the dies 51. To manage the gap between each of the dies 51 and the bonded object 6 with high accuracy in the bonding operation, the surface position of the die 51 is important. Here, heights may be measured at a plurality of positions in a plane of the die 51, and orientation of the die 51 or the bonded object 6 may be adjusted by a tilt mechanism during bonding. The tilt mechanism may be provided on any of the substrate stage 43, the substrate chuck 433, and the bonding head 423.

In step S1004, the control unit 441 drives the substrate stage 43 so as to position the die 51 on a bonding position of the bonded object 6. In other words, the die 51 is disposed on the bonding position of the bonded object 6. The control unit 441 measures the position of the substrate stage 43 by the interferometer 422, and feedback-controls the substrate stage 43 in real time, thereby positioning the substrate stage 43 with high accuracy.

In step S1005, the die 51 and the bonded object 6 are brought into contact with each other to perform the bonding operation. In step S1006, the storage unit 442 stores (updates) history information about bonding of the die 51 and the bonded object 6 in association with information on the collet 311 that is currently being used. The information on the collet 311 includes at least one of a piece of information on a type of the collet 311, a piece of identification information (e.g., management number) on the collet 311, a piece of information on a material of the collet 311, and a piece of information on a size of the collet 311. In the present exemplary embodiment, the history information about bonding of the die 51 and the bonded object 6 indicates history information about bonding of a plurality of dies and one or more bonded objects.

In the present exemplary embodiment, the history information about bonding of the die 51 and the bonded object 6 is managed for each collet by storage (update) in step S1006. The history information about bonding of the die 51 and the bonded object 6 includes at least one of a piece of information on the number of times of bonding, a piece of information on the number of times of picking up the die 51, a piece of information on a shape and a size of the bonded die 51, and a piece of information acquired during bonding. The information acquired during bonding is information acquired by the control unit 441 during bonding of the die 51 and the bonded object 6. The information acquired during bonding includes at least one of a current applied to press the die 51 against the bonded object 6, a pressure applied to the space in the collet 311, and time necessary for the collet 311 to hold the die 51.

The current applied to press the die 51 against the bonded object 6 is a current (pressing force) applied to press the die 51 in a case where the die 51 is bonded by being pressed against the bonded object 6. The current applied to press the die 51 is, for example, a current applied to the head (mechanism) including the collet 311. In a case where the history information about bonding of the die 51 and the bonded object 6 is information on the current applied to press the die 51, information on a target value of a current in control to apply the current to the head may be used. Alternatively, information on a current actually applied when the current is applied to the head, or a measurement result of the current applied to the head may be used.

The pressure applied to the space in the collet 311 is pressure applied to the space in the collet 311 in order to deform the die 51 during bonding of the die 51 and the bonded object 6. In a case where the history information about bonding of the die 51 and the bonded object 6 is information on the pressure applied to the space in the collet 311 in order to deform the die 51 during bonding, information on a target value in control may be used as with the above-described current. Alternatively, information on pressure actually applied or a measurement result of the pressure may be used. Alternatively, deformation of the collet 311 may be measured, the applied pressure may be calculated from the deformation of the collet 311, and a result of the calculation may be used.

The history information about bonding of the die 51 and the bonded object 6 is information obtained by accumulating value(s) of the information included in the history information based on the bonding history record(s), and the information in the storage unit 442 is updated every time the bonding processing is performed. For example, in the case of the information on the number of times of bonding, the accumulated number of times of bonding is stored in the storage unit 442 in association with the information on the collet 311. For example, in the case of the pressure information, an accumulated amount of applied pressure is stored in the storage unit 442 in association with the information on the collet 311. In other words, the history information about bonding of the die 51 and the bonded object 6 is accumulated information (information on an accumulated value of records of use) on the history (record) of bonding of the die 51 and the bonded object 6.

In step S1007, the control unit 441 determines whether all the dies 51 to be bonded to the bonded object 6 have been bonded. In a case where it is determined in step S1007 that all the dies 51 to be bonded to the bonded object 6 have been bonded (YES in step S1007), the bonded object 6 (first object) bonded with the plurality of dies 51 is carried out by a conveyance apparatus in step S1008, and the processing then ends. In a case where it is determined in step S1007 that not all the dies 51 to be bonded to the bonded object 6 have been bonded (NO in step S1007), the processing returns to step S2002.

In the present exemplary embodiment, after the bonding operation in step S1005, the determination in step S1007 and the processing in steps S2002 to S2004 are performed. Alternatively, the determination in step S1007 and the processing in steps S2002 to S2004 may be performed in parallel with the processing in steps S1003 to S1005. In a case where a die of a type different from the type of the die 51 that has been bonded (is being bonded) is to be bonded next, the processing in step S2001 is performed as necessary.

The number of dies 51 on the dicing frame 5 and the number of dies 51 to be bonded to the bonded object 6 may be different in some cases. Thus, carry-in of the bonded object 6 and carry-in of the dicing frame 5 are not synchronized with each other. In a case where shortage of the dies 51 on the dicing frame 5 occurs during the bonding processing for one bonded object 6, the next dicing frame is carried in. Further, in a case where the die 51 remains on the dicing frame 5 after the bonding processing for one bonded object 6 is completed, the remaining die 51 is used in bonding for the next bonded object 6.

Regarding the determination in step S2002, the collet 311 included in the pickup head 31 or the bonding head 423 may be damaged or contaminated after the collet 311 holds the die 51 a plurality of times. In a case where the collet 311 is damaged or contaminated, a pickup failure of the die 51 or dropping off of the die 51 due to shortage of holding force may occur. If an insufficient holding force is applied for holding the die 51, bonding accuracy at the time of bonding the die 51 to the bonded object 6 may be adversely affected. Thus, in the case where the collet 311 is damaged or contaminated, it is necessary to replace the collet 311. In the present exemplary embodiment, in step S2002, the control unit (determination unit) 441 determines whether to replace the collet 311 based on the history information about bonding of the die 51 and the bonded object 6, stored in the storage unit 442. Deterioration in holding performance of the collet 311 for holding the die 51 due to damage or contamination of the collet 311 depends on a material and a size of the collet 311. Thus, a replacement criterion is determined in advance for each collet 311. The control unit 441 determines whether to replace the collet 311 by comparing the previously determined replacement criterion (criterion value) of a target collet 311 (currently-used collet 311) with the history information about bonding of the die 51 and the bonded object 6.

The determination is performed based on the accumulated value of the information included in the history information about bonding of one or the plurality of dies 51 and the bonded object 6. For example, in a case where the accumulated value of history information exceeds the corresponding criterion value, it may be determined that replacement of the collet 311 is necessary. Alternatively, in a case where the accumulated values of two or more pieces of (plurality of types of) information exceed the corresponding criterion values, it may be determined that replacement of the collet 311 is necessary. Alternatively, in a case where the accumulated value of a predetermined piece or of a plurality of pieces of information exceeds the corresponding criterion value(s), it may be determined that replacement of the collet 311 is necessary. For example, in a case where the number of times of bonding exceeds a corresponding predetermined value (criterion value) and accumulated pressure values exceeds a corresponding predetermined value (criterion value), it may be determined that replacement of the collet 311 is necessary.

The type of collet used depends on the type of the die 51 to be bonded. Thus, the storage unit 442 manages the history information about bonding of the die 51 and the bonded object 6 for each collet, and updates the history information about bonding of the die 51 and the bonded object 6 (information on an accumulated value of records of use, i.e., use records) in association with information on the collet used for bonding.

Further, in the present exemplary embodiment, the example in which it is determined whether to replace the collet 311 based on the accumulated value of the used records is described, without limitation of the determination thereto. For example, the control unit (determination unit) 441 may predict a collet replacement timing from the information on the accumulated value of the use records. More specifically, the control unit (determination unit) 441 may predict the number of times of bonding until the replacement criterion is met, and a collet may be replaced when the number of times of bonding reaches the predicted number of times of bonding. The predicted information is not limited to the number of times of bonding, and may be other information included in the history information about bonding of the die 51 and the bonded object 6. The predicted information such as the number of times of bonding until replacement, the number of processed substrates until replacement, and a replacement date may be displayed on a display unit (display) under the control of a display control unit. The predicted information may be displayed in a list format or a calendar format.

The replacement criterion (criterion value) of the history information about bonding of the die 51 and the bonded object 6 may be updated (set) based on a record. For example, a pressure sensor may be provided in the collet 311, damage (wear) of the collet 311 may be predicted from a value of pressure when the die 51 is suctioned and held, and the replacement criterion may be updated based on a predicted result. Further, the replacement criterion may be updated based on data obtained from a plurality of bonding apparatuses.

In the present exemplary embodiment, the example is provided in which the control unit 441 in the bonding apparatus determines whether to replace the collet 311. However, the determination is not so limited. For example, the determination may be performed by an external information processing apparatus. In a case where the determination is performed by the external information processing apparatus, the information processing apparatus includes an acquisition unit that acquires information in which the history information about bonding of the die 51 and the bonded object 6 and the information on the collet 311 are associated with each other.

According to the present exemplary embodiment, replacement of the collet 311 can be determined without detecting the shape of the collet 311. In other words, the replacement of the collet 311 can be determined without stopping production to determine the replacement of the collet 311. Accordingly, it is possible to determine the replacement of the collet 311 while preventing a decrease in productivity, and to suppress occurrence of an error due to insufficient holding force of the collet 311. This is advantageous from a productivity standpoint.

In a second exemplary embodiment, information is used to determine replacement of a collet 311. In the first exemplary embodiment, the replacement of the collet 311 is determined based on the history information about bonding of the die 51 and the bonded object 6. In the present exemplary embodiment, replacement of the collet 311 is determined based on information about an inspection result of a first object in which the die 51 and the bonded object 6 are bonded.

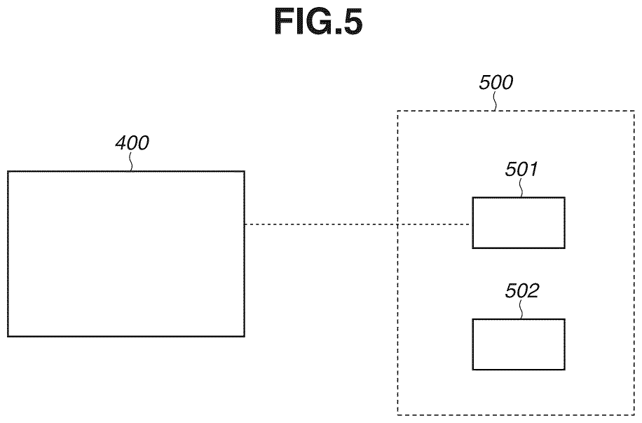

FIG. 5 is a schematic diagram illustrating an inspection apparatus 400 and a determination apparatus 500 according to the present exemplary embodiment. The inspection apparatus 400 inspects the first object in which the die 51 and the bonded object 6 are bonded using the bonding apparatus. The inspection apparatus 400 is configured to inspect the bonding accuracy between the die 51 and the bonded object 6, and to inspect, for example, misalignment (overlay accuracy) of a bonding position of the die 51 relative to a bonding position of the bonded object 6. Alternatively, the inspection apparatus 400 inspects at least one electric characteristic of the first object.

The inspection result of the first object is affected by various conditions of a bonding process. For example, in a case where the collet 311 is damaged or contaminated, a specific tendency appears in the inspection result of the first object. Thus, the determination apparatus 500 according to the present exemplary embodiment determines the replacement of the collet 311 based on the inspection result of the first object. The determination apparatus 500 may be disposed inside the bonding apparatus, may be disposed inside the inspection apparatus 400, or may be an information processing apparatus disposed outside the bonding apparatus and the inspection apparatus 400.

The determination apparatus 500 includes an acquisition unit 501 that acquires information about the inspection result of the inspection apparatus 400, and a determination unit 502 that determines the replacement of the collet 311 based on the information about the inspection result acquired by the acquisition unit 501.

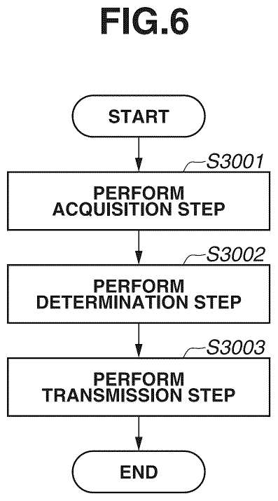

FIG. 6 is a flowchart of a process for determining the replacement of the collet 311 according to the present exemplary embodiment. First, in step S3001, the acquisition unit 501 acquires the information about the inspection result of the first object by the inspection apparatus 400 (acquisition step).

Next, in step S3002, the determination unit 502 determines the replacement of the collet 311 based on the information about the inspection result acquired in step S3001 (determination step). The determination unit 502 determines whether to replace the collet 311 by comparing the replacement criterion previously determined for each collet 311 with the information about the inspection result. In the determination, for example, in a case where a difference between the inspection result and an index value (e.g., design value) exceeds the predetermined value (i.e., criterion value and/or threshold), it may be determined that the replacement of the collet 311 is necessary.

Then, in step S3003, the determination unit 502 transmits information about a determination result (indicating whether to replace the collet 311) to the bonding apparatus (transmission step). In a case where the determination apparatus 500 is in the bonding apparatus, step S3003 may be omitted.

According to the present exemplary embodiment, as in the first exemplary embodiment, it is possible to determine the replacement of the collet 311 while preventing a decrease in productivity, and to suppress occurrence of an error due to insufficient holding force of the collet 311. This is advantageous from a productivity standpoint.

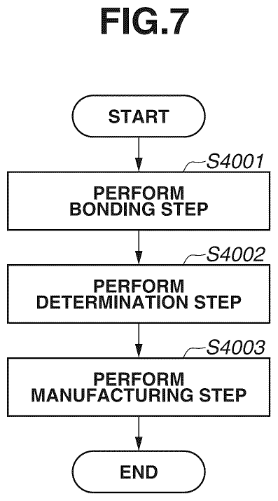

FIG. 7 is a flowchart of a method of manufacturing an article according to a third exemplary embodiment. In step S4001, a bonding step is performed in which a die 51 held by a collet 311 (first holding unit) and a bonded object 6 held by a substrate chuck 433 (second holding unit) are bonded. Next, in step S4002, a determination step is performed in which replacement of the collet 311 is determined based on the above-described history information about bonding of the die 51 and the bonded object 6 or the above-described information about the inspection result. Then, in step S4003, a manufacturing step is performed in which an article is manufactured from the first object obtained by bonding the die 51 and the bonded object 6.

Articles manufactured by the manufacturing method may include, for example, a semiconductor integrated circuit (IC) element, a liquid crystal display element, a color filter, a MEMS, a light-emitting diode (LED), a sensor, or an optical device.

The manufacturing step includes, for example, execution of packaging. By the manufacturing method, it is possible to manufacture an article while preventing a decrease in productivity.

The present disclosure is not limited to the above-described exemplary embodiments, and various modifications and variations can be made without departing from the spirit and scope of the present disclosure.

According to the exemplary embodiments, it is possible to provide the bonding apparatus capable of determining whether to replace a collet while preventing a decrease in productivity.

While the present disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims priority to and the benefit of Japanese Patent Application No. 2024-064427, filed Apr. 12, 2024, the entire content of which is incorporated by reference herein.

What is claimed is:

1. An apparatus for bonding a die and a bonded object, the apparatus comprising:
a holding unit configured to hold the die; and
a determination unit configured to determine replacement of the holding unit based on history information about bonding the die to the bonded object using the holding unit,
wherein the history information is an accumulated value of a use record when a plurality of dies is bonded to at least one of a plurality of bonded objects.

2. The apparatus according to claim 1, wherein the holding unit is a collet held by at least one of a pickup head and a bonding head.

3. The apparatus according to claim 1, further comprising a plurality of holding units, wherein the history information is managed for each holding unit of the plurality of holding units.

4. The apparatus according to claim 1, wherein the history information includes information on a number of times of bonding or information on a number of times of picking up the die.

5. The apparatus according to claim 1, wherein the history information includes at least one of a pressure applied to a space in the holding unit to deform the die during bonding, a current applied to a mechanism to press the die in a case where the die is bonded by being pressed against the bonded object, and a time for the holding unit to hold the die.

6. The apparatus according to claim 1, wherein the determination unit is further configured to perform the determination based on a plurality of types of information included in the history information.

7. The apparatus according to claim 1, wherein, in a case where a value included in the history information exceeds a criterion value, the determination unit is configured to determine the replacement of the holding unit.

8. The apparatus according to claim 1, wherein the determination unit is further configured to predict a replacement timing of the holding unit.

9. The apparatus according to claim 8, further comprising a display control unit configured to perform control to display, on a display unit, information about the replacement timing.

10. The apparatus according to claim 1, wherein a predetermined value used by the determination unit for the determination is updated when the holding unit holds the die.

11. The apparatus according to claim 10, wherein the update is based on information obtained from a plurality of bonding apparatuses.

12. A determination apparatus comprising:
an acquisition unit configured to acquire information about a holding unit and history information about bonding a die to a bonded object using the holding unit; and
a determination unit configured to determine replacement of the holding unit based on the history information.

13. A determination apparatus comprising:
an acquisition unit configured to acquire information about an inspection result of an object in which a die and a bonded object are bonded; and
a determination unit configured to determine replacement of a holding unit based on the acquired information,
wherein the holding unit is configured to hold the die.

14. The determination apparatus according to claim 13, wherein the inspection is of a position of the die relative to a position of the bonded object or of at least one electric characteristic of the first object.

15. A method of manufacturing, the method comprising:
bonding a die held by a first holding unit and a bonded object held by a second holding unit;
determining replacement of the first holding unit based on history information or inspection result information; and
manufacturing an article from an object in which the die and the bonded object are bonded,
wherein the history information is about bonding of the die and the bonded object using the first holding unit, and
wherein the inspection result information is about an inspection of the object.
